(19) United States
(12) Patent Application Publication
(10) Pub. No.: US 2006/0022556 A1
(43) Pub. Date: Feb. 2, 2006

(54) Quartz resonator package having a housing with thermally coupled internal heating element

(76) Inventors: David L. Bail, Carlisle, PA (US); Jeffrey K. Orner, Boiling Springs, PA (US)

Correspondence Address: Stephen B. Salai, Esq.;Harter, Secrest & Emery LLP, 1600 Bausch & Lomb Place, Rochester, NY, 14604-2711, US

(21) Appl. No.: 10/902,317

(22) Filed: Jul. 29, 2004

(51) Int. Cl. H01L 41/053

(52) U.S. Cl. 310/344

(57) ABSTRACT

A resonator package includes a quartz resonator and a heating element within a sealed housing, wherein the heating element is thermally coupled to an external wall of the housing. The heated external wall of the housing is thermally coupled to a substrate to heat a local region of the substrate. The heated local region of the substrate thermally stabilizes an associated oscillator control circuit and heater control circuit which are external to the housing.

### BACKGROUND OF THE INVENTION

1. Field of the Invention

The present invention relates to oscillators, and more particularly, to a resonator package wherein a quartz resonator and a heating element are disposed within a housing and the heating element is thermally coupled to the housing such that the heated housing heats the quartz resonator and a separate external component or subsystem.

2. Description of the Related Art

A crystal oscillator can be used as a frequency and time reference source. The frequency of a crystal oscillator is often temperature dependent. Yet, in many applications, the frequency of the crystal oscillator must remain stable despite changing ambient temperatures. In various types of electronic systems such as digital control devices, communications devices, and positioning devices the crystal oscillator must function under an environment of a severe temperature change.

In some positioning systems, for example, a receiver employs a crystal oscillator to maintain an accurate count of time with respect to an orbiting transceiver. In a global positioning system, the orbiting transceiver in a satellite begins transmitting a long, digital pattern, and the receiver begins running the same digital pattern at the same time. When the signal from the satellite reaches the receiver, the received digital pattern will lag behind the digital pattern run by the receiver. The length of the delay is equal to the travel time of the transmitted signal. The receiver multiplies the delay time by the speed of light to determine how far the signal traveled, which is the distance from the receiver to the satellite. Measurements from multiple satellites allow the receiver to identify its position. In order to make these measurements, the clocks in the receiver and the satellite must be highly synchronized, typically on the order of nanoseconds. Thus, any error in the crystal oscillator timing at the receiver can lead to errors in the calculated position.

One known solution is to utilize a temperature-compensated oscillator, such as a TCXO. A voltage variable capacitor is added to the oscillator so that the frequency can be shifted a small amount by a correction voltage developed by an associated thermistor network. This correction voltage causes the oscillator frequency to remain substantially constant as the ambient temperature changes. Because perfect cancellation is not possible, there remains some residual frequency drift as a function of temperature. Additionally, the frequency correction network tends to degrade oscillator phase noise characteristics as well as the short term stability of the oscillator.

Oven controlled crystal oscillators (OCXO) are well known in the industry. In the OCXO, the crystal oscillator is maintained at a controlled elevated temperature, higher than the greatest expected ambient temperature. Enhanced frequency stability is possible if a sufficiently accurate temperature feedback loop is employed.

Despite the advantages of the prior oscillators, a current need exists for an ovenized oscillator that exhibits a small package size and minimizes the required amount of printed circuit board. The need exists for a resonator package that can provide a temperature regulated quartz resonator, wherein the quartz resonator can be readily brought to a desired operating temperature. A further need exists for a resonator package that can provide thermal stability to external control circuitry associated with the quartz resonator.

### BRIEF SUMMARY OF THE INVENTION

The present invention provides a resonator package having a reduced thermal mass to be directly heated, while still providing thermal stability. The present resonator package further provides for internal heating of the quartz resonator as well as heating of external control circuitry. The resonator package is compatible with a variety of mechanisms for operably interconnecting the resonator package to an external substrate, such as a circuit board. These mechanisms include solder reflow, thermal epoxies and bonding agents which thermally couple the resonator package to the external substrate.

Generally, the resonator package provides a sealed housing in which the quartz resonator and a heating element are disposed, with the heating element being thermally coupled to an interior surface of an exterior wall of the housing. The resonator package is thus an enclosure for the quartz resonator as well as functioning as a heating source, wherein the heated resonator package becomes an active heating device applying heat to both the internal quartz resonator and external control circuitry such as the oscillator control circuit.

In one configuration, the present invention provides a resonator package for engaging a substrate, wherein the resonator package includes a sealed housing partially defined by a base wall, an exterior surface of the base wall selected to thermally contact the substrate, and the housing being free of an oscillator control circuit and a heater control circuit. A quartz resonator is retained within the housing and spaced from the base wall and a heating element is retained within the housing and thermally bonded to the base wall.

In further configurations, the heating element is sufficiently bonded to the base wall of the housing to conduct a majority of the heat generated by the heating element to the base wall. It is also contemplated the substrate can be one of a printed circuit board, a ceramic, a glass laminate, a circuit assembly or a polyamide, which can be disposed intermediate the exterior surface of the base wall and the oscillator circuit.

Further, the resonator package can employ any of a variety of heating elements such as a transistor die, a resistive element or a semiconductor.

The resonator package can also space the quartz resonator from the heating element by a sufficient distance such that the quartz resonator is predominately heated by the housing.

### BRIEF DESCRIPTION OF THE SEVERAL VIEWS OF THE DRAWING(S)

FIG. 1 is a cross sectional view showing the present resonator package thermally coupled to a substrate and associated control circuitry.

FIG. 2 is an exploded view of the resonator package.

### DETAILED DESCRIPTION OF THE INVENTION

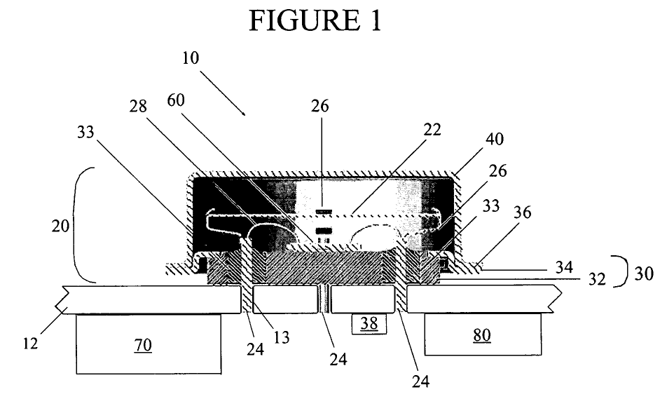

Referring to FIG. 1, a resonator package 10 is shown operably and thermally coupled to a substrate 12, wherein selected control circuitry such as an oscillator control circuit 70 and a heater (temperature) control circuit 80 are also connected to the substrate.

The substrate 12 can be any of a variety of constructions including, but not limited to a printed circuit board, a ceramic substrate, a circuit assembly or a polyamide, as well as a laminate or composite. The substrate 12 can include a plurality of plated apertures 13 for receiving corresponding leads of the resonator package 10.

The resonator package 10 includes a housing 20 for retaining a quartz resonator 22. The housing 20 includes an exterior wall which defines an interior to the housing and an exterior. Preferably, the exterior wall of the housing defines a sealed, or sealable interior. The exterior wall of the housing 20 includes a base wall 30 and a lid 40. In one configuration, the base wall 30 forms a bottom of the housing 20 and the lid 40 generally defines the sidewalls and a top wall of the housing. However, it is understood the components of the housing 20 can be alternatively constructed.

As seen in FIG. 1, the base wall 30 is formed by a central projecting pad 32 and a peripheral flange 34 connected to the projecting pad. The projecting pad 32 defines a contact area of the resonator package with the substrate 12 (or bonding area with the substrate). The projecting pad 32 includes a plurality of apertures 33 for receiving conductive leads 24. The leads 24 can being fixed within the apertures by any variety of materials such as epoxies, bonding agents or insulating material.

The peripheral flange 34 extends from the projecting pad 32 to provide a seating surface 36 for joining to the lid 40. Preferably, the peripheral flange 34 locates the seating surface 36 to be spaced from the plane of the bottom surface of the projecting pad 32. That is, the seating surface 36 is vertically spaced from the lower surface of the projecting pad 32. This vertical spacing is selected to reduce interference between the peripheral flange 36 and the substrate 12, thereby enhancing contact between the projecting pad 32 and the substrate. The projecting pad 32 thereby effectively projects to form a contact area with the substrate 12.

Preferably, at least the projecting pad 32 is formed of a heat conducting material, such as, but not limited, to cold rolled steel, copper or Kovar® alloyed metal, for example Kovar® (Fe54/Ni29/Co17) alloyed metal. It is understood the entire base wall 30 can be formed of these materials.

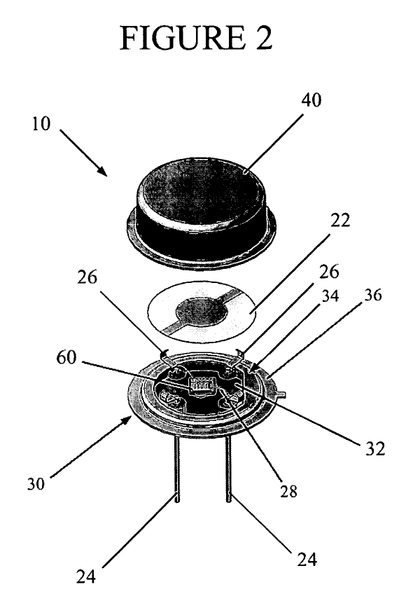

The lid 40 connects to the base wall 30, and particularly the peripheral flange 34 to generally close the housing. Although not required, it is contemplated the base wall 30 and the lid 40 are connected to form a sealed housing 20 and thus allow an evacuation and/or back filling of the housing. Thus, the housing 20 can be hermetically sealed. As seen in FIGS. 1 and 2, the lid 40 includes the top wall, sidewalls and a depending flange for cooperatively engaging the seating surface 36 of the peripheral flange 34.

While the lid 40 can be formed from a variety of materials, satisfactory materials have been found to include metals such as, but not limited, to cold rolled steel, copper or Kovar® (Fe54/Ni29/Co17) alloyed metal.

The quartz resonator 22 and a heating element 60 are located within the housing 20. A plurality of mounting posts 26 extend from the base wall 30 to engage and retain the quartz resonator 22 at a position spaced from the base wall. Preferably, the mounting posts 26 locate the quartz resonator 22 at a position so as to be spaced from each of the external walls of the housing 20. That is, the quartz resonator 22 is spaced from the base wall 30 and the lid 40.

The heating element 60 is thermally coupled to the base wall 30. Preferably, the heating element 60 is directly thermally coupled to the base wall 30, such that at least a majority of the heat generated by the heating element is conducted to the base wall. The thermal resistance between the heating element 60 and the base wall 30 is at least substantially minimized. A satisfactory bonding material has been found to include polyamide epoxy. A pair of conductors 28 extend from the leads 24 to the heating element 60, thereby providing electrical contact to the heating element. As seen in FIG. 1, the heating element 60 can be thermally coupled to the projecting pad 32 of the base wall 30.

The heating element 60 can be any of a variety of devices including, but not limited to a transistor die, a resistive element or a semiconductor.

In one configuration, a temperature sensor 38 is provided to generate a signal corresponding to a temperature within the housing 20. Depending upon the desired configuration, the temperature sensor 38 can sense a free space temperature within the housing 20, or alternatively, can be thermally coupled to the base wall 30, the mounting post 26, the lid 40 or the quartz resonator 22. Preferably, the temperature sensor 38 is external to the housing 20, however it is understood the temperature sensor can be disposed within the housing. The temperature sensor 38 can be any of a variety of configurations, including but not limited to thermistors.

It is also contemplated the temperature sensor 38 can be embedded within the base wall 30 or even external to the housing 20, wherein a calibration or coefficient can be employed in the heater control circuit 80.

As seen in FIG. 1, the leads 24 are disposed within apertures 13 in the substrate 12 so as to seat the external surface of the base wall 30 against the substrate. Thermal coupling of the base wall 30 to the substrate 12 can be enhanced by any of a variety of coupling media including, but not limited to solder, thermal epoxies or bonding agents. The thermal bonding of the heating element 60 to the interior surface of the exterior wall of the housing 20 includes a thermal conductor contacting at least substantially all the available heated surface of the heating element. It is also contemplated that the heating element 60 can be located with a recess or well in the base wall 30, wherein a thermal conductor is used to retain the heating element.

As seen in the figures, the oscillator control circuit 70 and the heater control circuit 80 are located external to the housing 20. That is, the sealed volume retaining the quartz resonator 22 and the heating element 60 is free of the oscillator control circuit 70 and the heater control circuit 80. The oscillator control circuit 70 and the heater control circuit 80 are thermally connected to the substrate 12 and electrically (operably) connected to the quartz resonator 22 and the heating element 60, respectively. In a preferred construction, the oscillator control circuit 70 and the heater control circuit 80 are proximal to the thermal coupling of the base wall 20 and the substrate 12. Depending upon the configuration of the substrate 12, the circuits 70 and 80 can be located on an opposing surface of the substrate. Alternatively, the circuits 70 and 80 can be located on the same side of the substrate 12 as the resonator package 10.

The housing 20 serves as both the enclosure for the quartz resonator 22 as well as a heating device. The heating element 60, being thermally bonded to an exterior wall of the housing 20 allows the housing to act as an active heating device applying heat to the substrate 12 and the external control circuits 70, 80.

To assemble the components relative to the substrate 12, the resonator package 10 is thermally connected to the substrate by a thermally conductive mechanism, such as thermal epoxy, bonding agents or solder reflow. The outside surface of the base wall 30, such as the projecting pad 32, is directly thermally coupled or bonded to the substrate 12. The oscillator control circuit 70 and the heater control circuit 80 are electrically connected to the substrate 12 and hence the resonator package 10. Preferably, the circuits 70, 80 are in sufficient thermal contact with the substrate 12 to readily absorb heat from the substrate.

As a current is delivered to the heating element 60, heat is generated and is immediately conducted to the base wall 30. As the base wall 30 is a thermal conductor, the base wall promptly rises to the corresponding temperature. Heat from the base wall 30 heats both the lid 40, the quartz resonator 22 as well as the adjacent portion of the substrate 12 via the thermal coupling of the resonator package 10 to the substrate. The heated substrate 12 thus heats the associated oscillator control circuit 70 and heater control circuit 80.

As only the quartz resonator 22, the heating element 60 and the optional temperature sensor 38 are disposed within the housing 20, the sizing of the resonator package 10 can be substantially reduced. As the size of the resonator package 10 is reduced, the proximity of the heating element 60 to the quartz resonator 22 is increased without requiring direct thermal contact, thereby decreasing the required time for bringing the quartz resonator to operating temperature.

Thus, the resonator package 10 provides a sealed housing 20 retaining only the quartz resonator 22, the heating element 60 thermally coupled to an external wall of the housing and an optional temperature sensor 38, wherein both the quartz resonator 22 (internal to the housing) and the control circuitry (external to the housing) are heated by the heating element.

As the resonator package 10 does not include particularly sensitive components, the resonator package can be readily bonded to the substrate 12 by any of a variety of mechanisms, including but not limited to thermal epoxy, bonding agents or solder reflow. Further, as the resonator package 10 is reflow compatible, heating of the substrate 12, such as a circuit board, with which the resonator package is assembled, eliminates the need for additional thermal masses, such as a heat sinks or oven blocks for thermally conditioning the oscillator 70 and heating 80 circuits.

Thus, the present resonator package 10 avoids the limitations of previous configurations in which the quartz resonator is directly heated, which configuration does not provide adequate heating of the associated control circuitry and particularly, such control circuitry which is external to the housing retaining the quartz resonator. The direct application of heat to the quartz resonator employed in prior systems tends to adversely affect behavior of the quartz resonator.

Thus, the resonator package 10 provides the housing 20 defined by an exterior wall, with a heating element 60 thermally coupled to an interior surface of the exterior wall. The quartz resonator 22 is spaced from the interior surface of the exterior wall, and the exterior wall is thermally bonded to the substrate 12 to provide thermal stability to the externally located oscillator circuit 70 and temperature control circuitry 80.

While there have been described what are presently believed to be the preferred embodiments of the present invention, those skilled in the art will realize that other and further configurations can be made without departing from the spirit and scope of the invention, and it is intended to include all such further modifications and changes as come within the true scope of the invention.

1. A resonator package for engaging a substrate, the resonator package comprising:
(a) a sealed housing partially defined by a base wall, an exterior surface of the base wall selected to thermally contact the substrate, the housing being free of an oscillator control circuit and a heater control circuit;
(b) a quartz resonator retained within the housing and spaced from the base wall; and
(c) a heating element retained within the housing and thermally bonded to the base wall.

2. The resonator package of claim 1, wherein the heating element is sufficiently bonded to the base wall to conduct a majority of the heat generated by the heating element to the base wall.

3. The resonator package of claim 1, further comprising an oscillator circuit external to the housing and operably connected to the quartz resonator.

4. The resonator package of claim 3, wherein the substrate is intermediate the oscillator circuit and the housing.

5. The resonator package of claim 1, wherein the substrate is one of a printed circuit board, a ceramic, a glass laminate, a circuit assembly or a polyamide and is disposed intermediate the exterior surface of the base wall and the oscillator circuit.

6. The resonator package of claim 5, wherein the exterior surface of the base wall defines a land area thermally coupling the base wall to the substrate.

7. The resonator package of claim 1, further comprising a heating element control circuit external to the housing and operably connected to the heating element.

8. The resonator package of claim 1, wherein the base wall is a thermal conductor.

9. The resonator package of claim 1, wherein the heating element is one of a transistor die, a resistive element and a semiconductor.

10. The resonator package of claim 1, wherein the quartz resonator is predominantly heated by the housing.

11. The resonator package of claim 9, wherein the quartz resonator is one of conductively, radiatively or convectively heated by the housing.

12. The resonator package of claim 1, wherein the exterior surface of the base wall defines a projecting pad and the housing includes a peripheral flange, the peripheral flange selected to be sufficiently spaced from the projecting pad to ensure thermal coupling of the projecting pad and the substrate.

13. The resonator package of claim 1, wherein the quartz resonator is spaced from the heating element by a sufficient distance such that the quartz resonator is predominately heated by the housing.

14. The resonator package of claim 1, wherein the quartz resonator is spaced from the heating element by free space.

15. The resonator package of claim 1, wherein the housing is evacuated.

16. The resonator package of claim 1, wherein the housing is backfilled with a predetermined gas.

17. A resonator package, comprising:
(a) a housing having a housing wall defining a sealed cavity;
(b) a quartz resonator retained within the cavity and spaced from an interior surface of the housing wall; and
(c) a heating element thermally bonded to the interior surface of the housing wall and separated from the quartz resonator by a free space distance,
the housing being free of an oscillator control circuit and a
heating element circuit.

18. The resonator package of claim 17, wherein the housing wall includes a base wall having an exterior surface selected to thermally couple to a substrate, wherein the heating element is thermally coupled to the base wall.

19. The resonator package of claim 17, further comprising an oscillator control circuit thermally coupled to the base wall through the substrate and electrically connected to the quartz resonator.

20. A resonator package, comprising:
(a) a sealed housing at least partially defined by a housing wall;
(b) a quartz resonator retained within the housing and spaced from an interior surface of the housing wall;
(c) an oscillator control circuit external to the housing and operably connected to the quartz resonator;
(d) a heating element thermally bonded to the interior surface of the housing wall and separated from the quartz resonator by a free space; and
(e) a heating element control circuit external to the housing and operably connected to the heating element.

21. The resonator package of claim 20, wherein the housing wall includes a thermal conducting base wall selected to thermally couple to an external substrate.

22. A method of controlling a temperature of a quartz resonator, the method comprising:
(a) thermally coupling a sealed housing to a substrate, the sealed housing retaining the quartz resonator;
(b) operably connecting an external oscillator control circuit to the quartz resonator; and
(c) selectively energizing a heating element thermally bonded to an interior surface of the housing to control a temperature of the quartz resonator, the quartz resonator being spaced from the heating element.

23. The method of claim 22, further comprising energizing the heating element to heat the external oscillator control circuit.

24. The method of claim 22, further comprising separating the heating element from the quartz resonator by a free space distance.

25. The method of claim 22, further comprising backfilling the housing with a gas.

26. The method of claim 22, further comprising evacuating the housing.

27. A method of controlling a temperature of a quartz resonator, the method comprising:
(a) connecting a heating element thermally bonded to an interior surface of a wall of a sealed housing to a heating element control circuit external to the housing;
(b) connecting a quartz resonator located within the sealed housing and spaced from the heating element to an oscillator control external to the housing; and

28. The method of claim 27, further comprising selectively energizing the heating element to conductively heat the housing.
